(19) United States
(12) Patent Application Publication
(10) Pub. No.: US 2008/0236881 A1
(43) Pub. Date: Oct. 2, 2008

(54) MULTILAYER PRINTED WIRING BOARD AND METHOD FOR MANUFACTURING THE SAME

(76) Inventor: Shinji Tanaka, Tokyo (JP)

Correspondence Address: Jackson Chen;NEC Corporation of America, 6535 N. State Hwy. 161, Irving, TX, 75039, US

(21) Appl. No.: 12/056,705

(22) Filed: Mar. 27, 2008

(30) Foreign Application Priority Data
Mar. 27, 2007 (JP) 2007-081544

(51) Int. Cl. H05K 1/02; H05K 3/42

(52) U.S. Cl. 174/266; 29/852

(57) ABSTRACT

A multilayer printed wiring board includes a first insulating layer, a pair of second insulating layers sandwiching therebetween the first insulating layer, a pair of internal-layer wiring trace formed between the first insulating layer and the second insulating layer, and an external-layer wiring trace formed on the exposed surface of the second insulating layer. A hollow cylindrical via-plug is formed on the inner wall of a first through-hole penetrating through the first insulating layer and connects together the internal-layer wiring traces with each other. A second via-plug formed inside the first via and isolated therefrom by insulating resin connects together the external-layer wiring traces.

This application is based upon and claims the benefit of priority from Japanese patent application No. 2007-081544 filed on Mar. 27, 2007, the disclosure of which is incorporated herein in its entirety by reference.

### BACKGROUND OF THE INVENTION

1. Field of the Invention

The present invention relates to a multilayer printed wiring board and a method for manufacturing the same.

2. Description of the Related Art

A multilayer printed wiring board is used for mounting thereon one or more electronic parts such as semiconductor chips in electronic equipment. The multilayer printed wiring board includes a plurality of insulating layers, wiring traces (wiring patterns) formed between the insulating layers or on an exposed surface of the outermost insulating layer, and a plurality of via-plugs that penetrate through the insulating layers so as to connect together the wiring traces of different layers.

To fabricate the multilayer printed wiring board, a stacked body is first manufactured which includes a plurality of insulating layers and wiring traces intervening therebetween. A pair of conductive layers are formed on the top and bottom surfaces of the stacked body. After forming through-holes penetrating through the stacked body, via-plugs are formed on the inner wall of the through-holes so that the different wiring traces are connected to one another. Further, the conductive layers each formed on the exposed surface of the stacked body are patterned to form external-layer wiring traces or surface wiring traces.

The above structure of the multilayer printed wiring board is described, for example, in Patent Publication JP-2001-244633-A1.

Along with recent development of smaller dimensions and higher performance of electronic equipment, there is an increasing demand for a higher wiring density of the multilayer printed wiring boards, and accordingly, smaller width and pitch of the wiring traces and through-holes is also desired in the multilayer printed wiring boards. However, whereas it is relatively easy to reduce the width and pitch of the wiring traces between the insulating layers or on the exposed surface because of the recent improvement of the photolithographic patterning technique, it is difficult to reduce the diameter and pitch of the through-holes. This is partly because the through-holes are generally formed by means of a drill, the size of which is difficult to further reduce. In such a circumstance that the dimensions of the through-holes are affected by the size of the drill, there arises a problem that the dimensions of the through-holes hinders the wiring density of the multilayer printed wiring board from being increased.

### SUMMARY OF THE INVENTION

The present invention has been made in view of the foregoing circumstances, and it is therefore an object of the present invention to provide a multilayer printed wiring board which is capable of being increased in the wiring trace density. It is another object of the present invention to provide a method for manufacturing such a multilayer printed wiring board.

The present invention provides a method for manufacturing a multilayer printed wiring board, including: forming a stacked body that includes a first insulating layer, a second insulating layer disposed on a surface of the first insulating layer, and an internal-layer wiring trace formed between the first insulating layer and the second insulating layer; forming a first through-hole that penetrates through the stacked body; forming a first conductive layer at least on the inner wall of the first through-hole to form a hollow cylindrical conductive plug therein; forming a recessed-hole penetrating through the second insulating layer, the recessed-hole having a diameter larger than a diameter of the first through-hole and coaxial therewith; embedding a resin layer inside the hollow cylindrical conductive plug and within the recessed-hole to form an insulating plug penetrating through the stacked body; forming a second through-hole within the insulating plug penetrating therethrough; and forming a second conductive layer within the second through-hole to form a conductive plug penetrating the stacked body.

The present invention also provides a multilayer printed wiring board including: a stacked body including a first insulating layer, a pair of second insulating layers sandwiching therebetween the first insulating layer, a pair of internal-layer wiring traces each formed between the first insulating layer and one of the second insulating layers, and a pair of external-layer wiring traces each formed on an exposed surface of a corresponding one of the second insulating layers, the first insulating layer including therein a first through-hole, the first and second insulating layers including therein a second through-hole coaxial with the first through-hole and isolated therefrom by an insulating plug disposed therebetween; a first via-plug formed on the inner wall of the first through-hole to connect together the internal-layer wiring traces with each other; a second via-plug formed on the inner wall of the second through-hole to connect together the external layer wiring traces with each other.

In accordance with the multilayer printed wiring board and the method for manufacturing the multilayer printed wiring board of the present invention, the occupied area of the via-plugs can be reduced by forming the second plug within the first via-plug, making it easy to increase the wiring trace density of the multilayer printed wiring board.

The above and other objects, features and advantages of the present invention will be more apparent from the following description, referring to the accompanying drawings.

### BRIEF DESCRIPTION OF THE DRAWINGS

FIG. 1 is a sectional view of a multilayer printed wiring board according to an embodiment of the present invention;

FIGS. 2 to 11 are sectional views showing consecutive steps of a process for manufacturing the multilayer printed wiring board of FIG. 1;

FIG. 12 is a sectional view of a package wherein electronic parts are mounted on the top and bottom surfaces of the multilayer printed wiring board of FIG. 1;

FIGS. 13 to 15 are sectional views showing consecutive steps of a process for manufacturing the multilayer printed wiring board of FIG. 12;

FIG. 16 is a sectional view showing a step of a process for manufacturing a conventional multilayer printed wiring board; and

FIG. 17 is a sectional view showing a package including the conventional multilayer printed wiring board of FIG. 16.

### DETAILED DESCRIPTION OF THE INVENTION

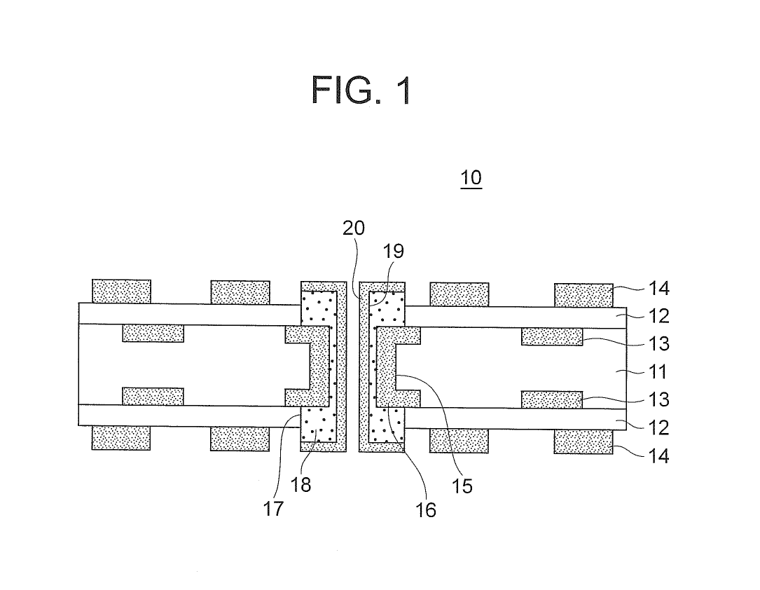

Hereinafter, an exemplary embodiment of the present invention will be described in detail with reference to the accompanying drawings. FIG. 1 is a sectional view of a multilayer printed wiring board according to an embodiment of the present invention. The multilayer printed wiring board, generally designated at numeral 10, includes a first insulating layer 11 formed from a prepreg, a pair of internal-layer wiring traces 13 each formed separately on the top or bottom surface of the first insulating layer 11, a pair of second insulating layers 12 sandwiching therebetween the first insulating layer 11 with an intervention of the internal-layer wiring traces 13, and a pair of external-layer wiring traces 14 formed on the exposed surface of the respective second insulating layers 12.

The second insulating layers 12 are made of thermosetting resin, and the external-layer wiring traces 14 are formed on the top and bottom surfaces of the stacked body. In the figure, the patterned shape of the internal-layer wiring traces 13 and external-layer wiring traces 14 is schematically illustrated. The multilayer printed wiring board 10 further includes a plurality of combination through-holes, one of which is illustrated in FIG. 1, penetrating through the first and second insulating layers 11 and 12.

The combination through-holes each include a first through-hole 15 and a second through-hole 19, which are coaxially formed with each other, wherein the first through-hole 15 encircles the second through-hole 19. The first through-hole 15 is formed penetrating through the first insulating layer 11. A first via-plug 16 is formed within the first through-hole 15 by plating the inner wall of the first through-hole 15, connecting both the internal-layer wiring traces 13 with each other. The first via-plug is of a hollow cylindrical shape. The combination through-holes are also associated with a recessed-hole 17 penetrating through the second insulating film and stopped on the surface of the first insulating film 11. The recessed-hole 17 is larger in diameter than the first through-hole 15, with the central axis of the recessed-hole 17 coinciding with that of the first through-hole 15.

Within the first through-hole 15 and recessed-hole 17, there is provided an insulation plug 18, which is made of a thermosetting resin and extends through the hollow cylindrical first via-plug 16 in the axial direction and at the central position thereof. The second through-hole 19 penetrates through the insulating plug 18. The insulating plug 18 is made of, for example, an ink material.

A second via-plug 20 is formed within the second through-hole 19 by plating the inner wall of the second through-hole 19 to connect both the external-layer wiring traces 14 with each other. The external-layer wiring traces 14 are formed also by plating the top surface and bottom surface of the insulating plug 18. The first and second via-plugs 16 and 20 and recessed-hole 17 are coaxially formed to extend in the direction perpendicular to the surface of the multilayer printed wiring board 10.

In the above structure of the multilayer printed wiring board 10 of the present embodiment, the first via-plug 16 connecting both the internal-layer wiring traces 13 with each other and the second via-plug 20 connecting both the external-layer wiring traces 14 with each other are disposed with their central axes coinciding with each other. This structure provides a smaller occupied area for the via-plugs, whereby the wiring density of the multilayer printed wiring board 10 can be increased with ease.

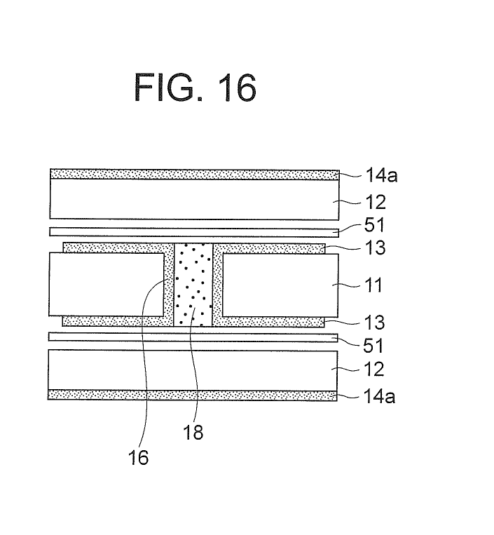

In an ordinary structure of the conventional multilayer printed wiring board shown in FIG. 16, the characteristic impedance is matched by providing the structure wherein a signal wiring layer and a ground wiring layer oppose to each other with an intervention of an insulating layer. However, this technique is difficult to employ for the via-plugs, whereby mismatching of the characteristic impedance may occur to cause signal noise due to signal reflection at the via-plugs.

In the multilayer printed wiring board 10 of the present embodiment, the first via-plug 16 and second via-plug 20 are formed in a coaxial structure. Therefore, by constructing the first via-plug 16 and second via-plug 20 as the signal wiring layer and ground wiring layer, the characteristic impedance thereof can be matched with ease to those of the other wiring portions, thereby suppressing occurrence of the reflection noise. In an alternative, by constructing the first via-plug 16 and second via-plug 20 as a power source wiring layer and a ground wiring layer, the loop inductance in the multilayer printed wiring board can be reduced.

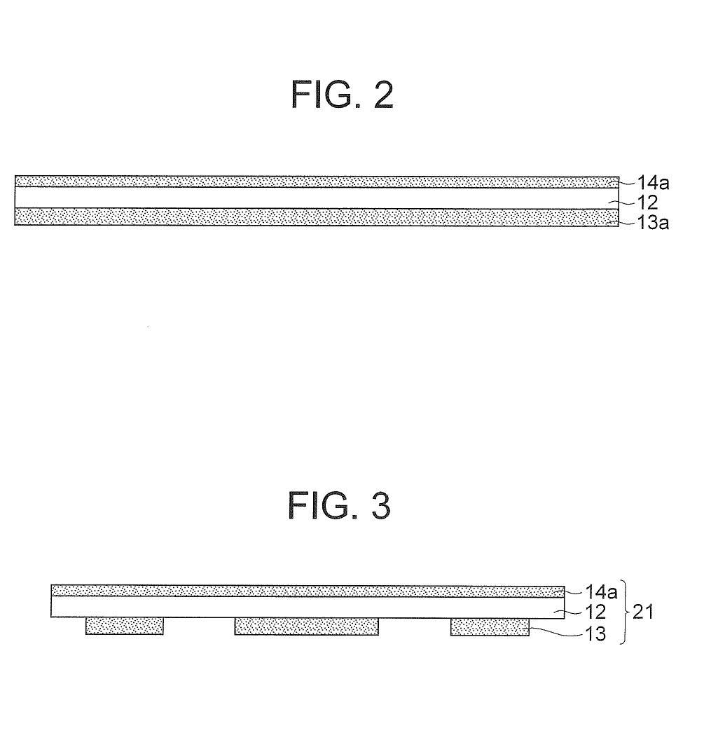

FIGS. 2 to 11 are sectional views showing consecutive steps of a process for manufacturing the multilayer printed wiring board 10 of FIG. 1. First, as shown in FIG. 2, conductive layers 14a and 13a made from copper are formed on the top and bottom surfaces of a insulator body configuring the second insulating layer 12. Then, the conductive layer 13a thus formed on the bottom surface of the second insulating layer 12 is patterned so as to form the internal-layer wiring trace 13. In this process, a pair of wiring members 21 shown in FIG. 3 is formed for a multilayer printed wiring board 10.

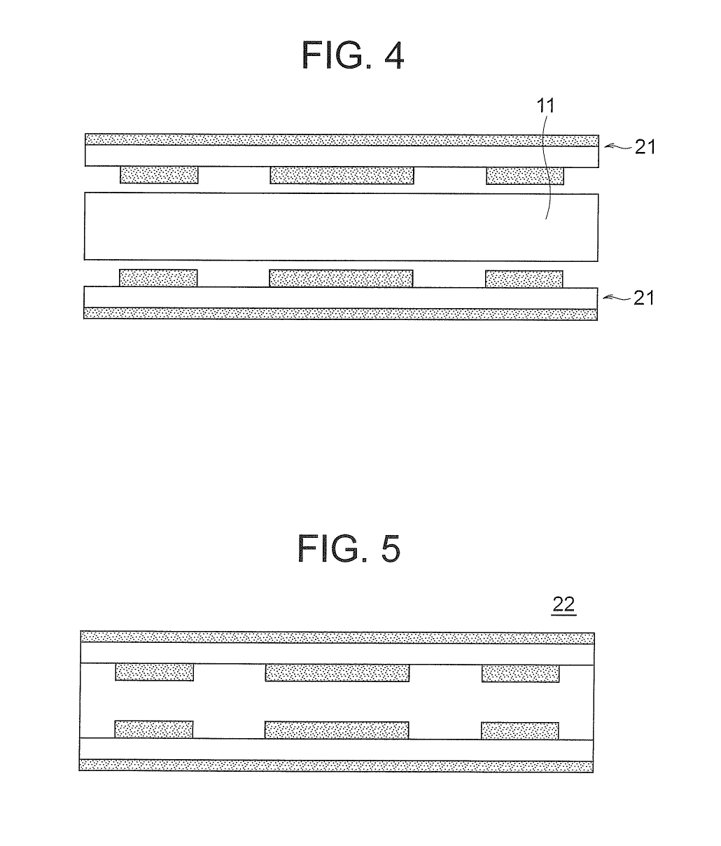

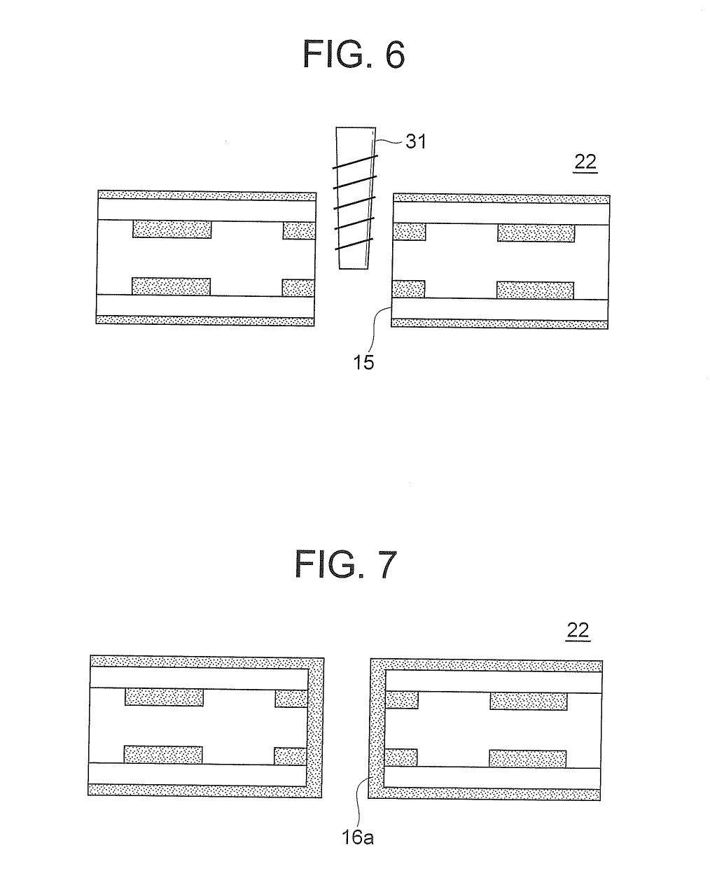

Subsequently, as shown in FIG. 4, the first insulating layer 11 formed from a prepreg is interposed between the pair of wiring members 21. Thereafter, a pressing treatment is conducted from the outer surface of both the wiring members 21, thereby forming a stacked body 22 shown in FIG. 5. Subsequently, as shown in FIG. 6, the stacked body 22 is subjected to a boring treatment using a drill 31 to form the first through-holes 15. Further, by using a plating technique, a conductive layer 16a is formed on the entire surface of the stacked body 22 including the inner wall of the first through-holes 15, as shown in FIG. 7.

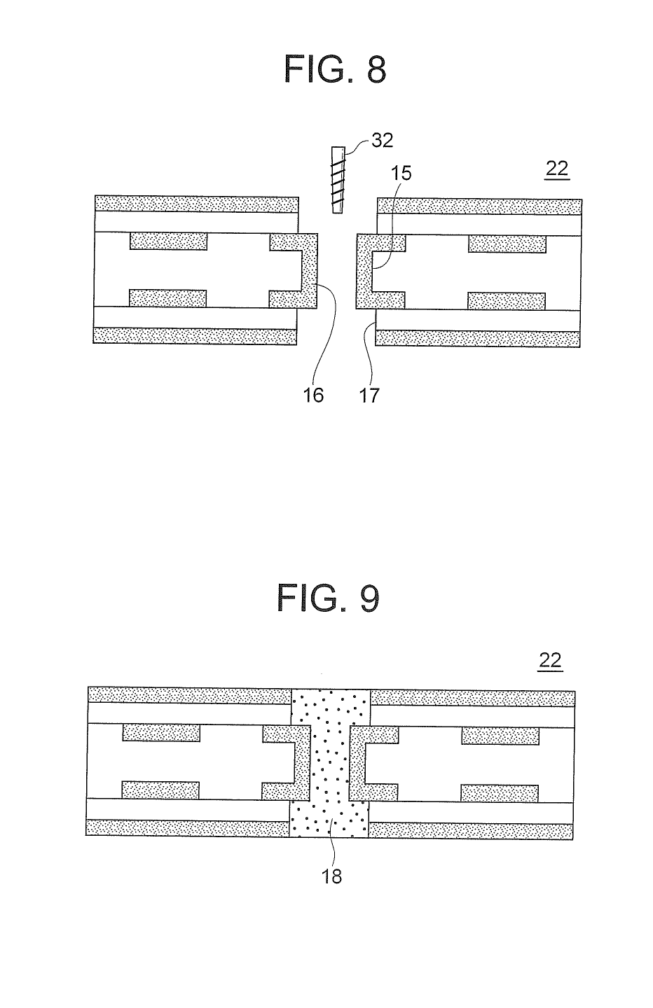

Subsequently, as shown in FIG. 8, a routing machine having a high-accuracy drilling performance is used to form the recessed-holes 17 that are larger in diameter than the first through-holes 15 with the central axis thereof coinciding with that of the first through-holes 15. The drilling process is performed until the internal-layer wiring traces 13 are exposed from the top surface and bottom surface of the stacked body 22. For this drilling process, a technique which is so-called “counter-boring” process is employed using the routing machine having a higher positional accuracy with respect to the depthwise direction of the object surface.

The portion of the conductive layer 16a left on the inner wall of the first through-holes 15 configures the hollow cylindrical first via-plug 16. In order to enhance the positional accuracy in the depthwise direction of the object surface in the counter-boring process, a technique which detects an electric contact may be used between the routing drill 32 and the conductive layer, as described, for example, in Patent Publication JP-1998-022643-A1.

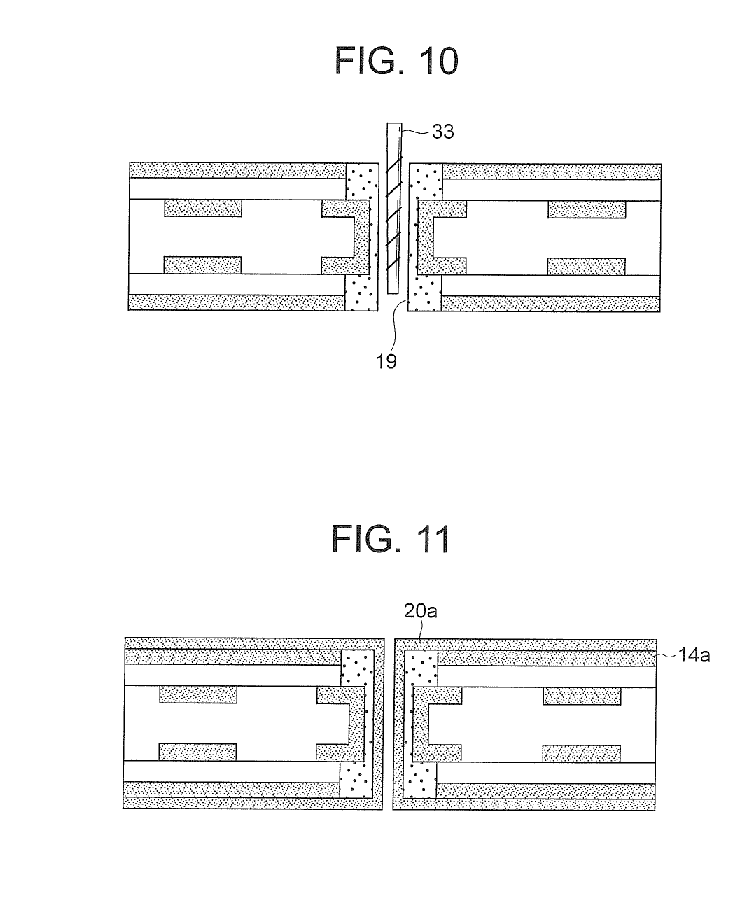

Subsequently, using a screen printing technique, a thermosetting resin (padding ink) is embedded in the first through-holes 15 and recessed-holes 17. The thermosetting resin is subsequently cured by baking and flattened by lightly polishing the surface thereof, thereby forming the insulating plug 18 (FIG. 9). Thereafter, as shown in FIG. 10, using a drill 33 having a diameter which is smaller than the inner diameter of the first via-plugs 16, the second through-holes 19 are formed within the insulating plug 18 in such a manner that the central axis of the second through-holes 19 coincide with the central axis of the first through-holes 15.

Subsequently, as shown in FIG. 11, using a plating technique, a conductive layer 20a is formed on the entire surface of the stacked body 22 including the inner wall of the second through-holes 19. Thereafter, the conductive layers 14a on the second insulating layers 12 and conductive layer 20a are patterned by selective etching to configure the external-layer wiring traces 14. Thereby, the multilayer printed wiring board 10 shown in FIG. 1 is completed. The portion of the conductive layer 20a which is left on the inner wall of the second through-holes 19 configures the second via-plugs 20 shown in FIG. 1.

It is to be noted in the above embodiment that the wiring traces 13 and 14 including four layers are formed. However, it is also possible to form wiring traces including six or more layers by stacking at least two layers of the wiring members 21 onto the first insulating layer 11. In this case, the conductive layer 14a which is not exposed on the surface of the stacked body 22 should be patterned into a wiring trace prior to stacking the insulator bodies. It is also possible to form a multilayer printed wiring trace including three wiring traces, such as including only a single external-layer wiring trace and two external-layer wiring traces or only a single internal-layer wiring trace and two internal-layer wiring traces.

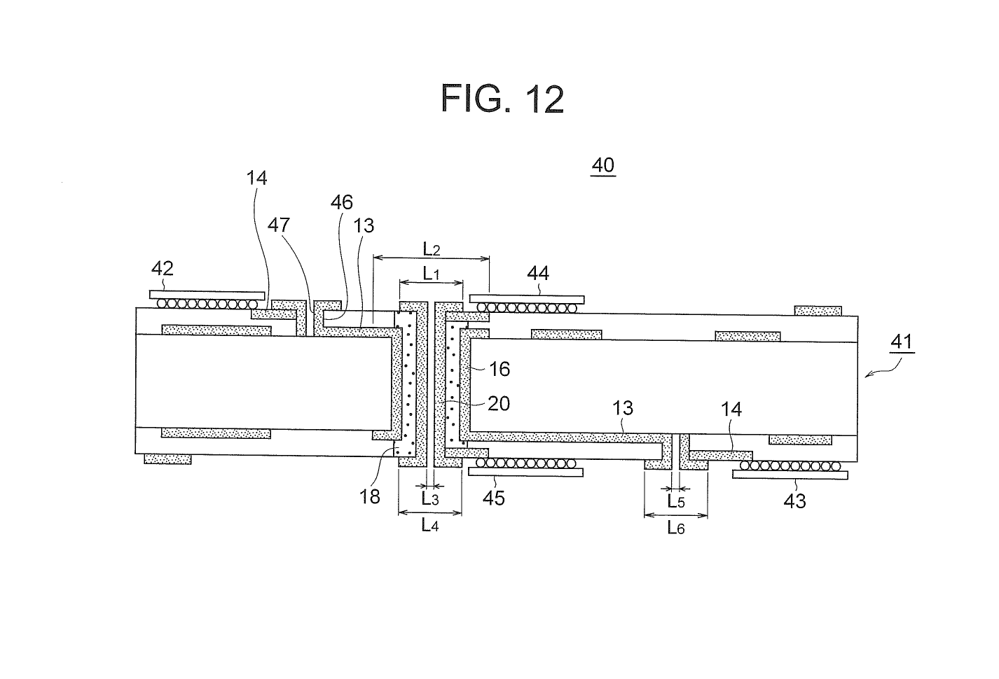

FIG. 12 shows an example of a package including the multilayer printed wiring board wherein electronic equipment are mounted on the multilayer printed wiring layer. The package, generally designated at numeral 40, includes the multilayer printed wiring board 41 and four electronic equipment, e.g., semiconductor chip 42 to 45 mounted on the top and bottom surfaces of the multilayer printed wiring board 41. The multilayer printed wiring board 41 includes recessed-holes, i.e., via-holes 46 each having a small diameter and penetrating through a corresponding second insulating layer 12. Third via-plugs, referred to as blind via-plugs 47, each of which connects together the internal-layer wiring trace 13 and external layer wiring trace 14, are formed within the via-holes 46. In this structure, the multilayer printed wiring board 41 is different in the structure thereof from the multilayer printed wiring board 10 of FIG. 1. The other structure of the multilayer printed wiring board 41 in FIG. 12 is similar to that shown in FIG. 1.

The semiconductor chips 44 and 45 are connected with each other via the external layer wiring trace 14 and the second via-plug 20. The semiconductor chips 42 and 43 are connected with each other via the external-layer wiring traces 14, third via-plugs 47, internal-layer wiring traces 13 and first via-plugs 16.

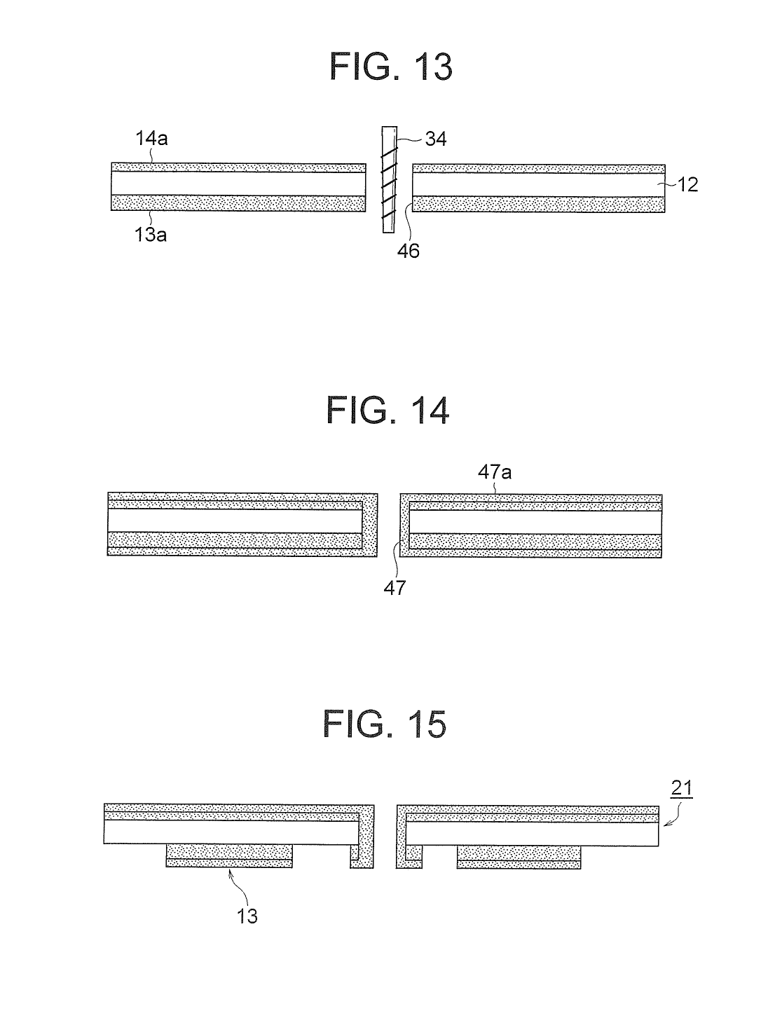

FIGS. 13 to 15 are sectional views showing consecutive steps of a process for manufacturing the multilayer printed wiring board 41 used in the package 40. The method for manufacturing the multilayer printed wiring board 41 is substantially the same as the method for manufacturing the multilayer printed wiring board 10 shown in FIGS. 2 to 11 except that the third via-plugs 47 are formed in the step of forming the wiring member 21.

Subsequent to the manufacturing step shown in FIG. 2, via-holes 46 penetrating through the second insulating layer 12 and conductive layers 13a and 14a are formed, as shown in FIG. 13, by using a drill 34. Thereafter, using a plating technique, a conductive layer 47a is formed on the entire surface of the stacked body including the inner wall of the via-holes 46, as shown in FIG. 14. The portion of the conductive layer 47a formed on the inner wall of the via-holes 46 configures the third via-plugs 47.

Subsequently, a portion of the conductive layer 14a and conductive layer 47a formed on the bottom surface of the second insulating layers 12 are patterned so as to form the internal-layer wiring traces 13. As a result, the wiring member 21 shown in FIG. 15 is formed. The subsequent steps are carried out similarly to the steps of FIGS. 4 to 11.

The first via-plugs 16 have, as shown in FIG. 12, an inner diameter L1 of, for example, 0.55 mm and a land diameter L2 of, for example, 0.9 mm. The second via-plugs 20 have an inner diameter L3 of, for example, 0.15 mm and a land diameter L4 of, for example, 0.6 mm. The thickness of the second insulating layer 12 is, for example, 0.1 mm. The third via-plugs 47 have an inner diameter L5 of, for example, 0.1 mm and a land diameter L6 of, for example, 0.4 mm. The term “land” as used herein means a portion of the wiring trace which is formed as an integral body of the via-plug and formed on the top or bottom surface portion of the insulating film around the via-plugs.

In the package 40 of FIG. 12, for connecting together the semiconductor chips 42 to 45, the first via-plugs 16 and second via-plugs 20 having central axes thereof coincided with each other for reducing the occupied area of the via-plugs in the multilayer printed wiring board 41. Since the third via-plugs 47 are formed to have a significantly smaller diameter compared to the via-plugs 16, the density of the multilayer printed wiring board 41 can be effectively increased. Additionally, since the third via-plugs 47 have a small length compared to the via-plugs 16 and 20, the stray capacitance involved with the third via-plugs 47 is also small, which sufficiently suppresses waveform distortion of the signal transferring via the third via-plugs 47.

It is to be noted that although Patent Publication JP-56-100494-A1 describes another method for manufacturing a multilayer printed wiring board having a structure such that a via-plug is formed within another via-plug, the structure obtained by the present invention is different from the structure shown in this publication. More specifically, the structure described in the publication shown in FIG. 16 is such that the first via-plugs 16 are formed prior to forming the stacked body 22, and not formed in the through-holes penetrating through the second insulating films.

In the structure shown in FIG. 16, the internal-layer wiring traces 13 are formed on the top and bottom surfaces of the first insulating layer 11 during the step wherein the first via-plugs 16 are formed. Therefore, the internal-layer wiring traces 13 cannot be formed on the inner surface of the second insulating layers 12, on which a prepreg layer 51 is formed. For this reason, the second insulating layer 12 cannot be provided with via-plugs, such as via third plugs 47, which connect together the internal-layer wiring trace 13 and the external-layer wiring traces.

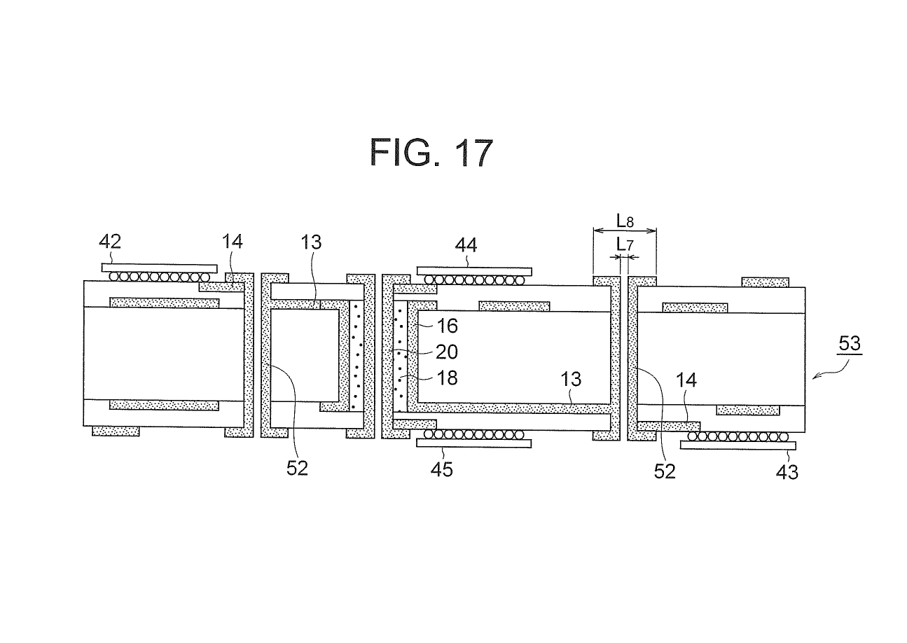

In the structure of the patent publication described above, there emerges a need for forming via-plugs 52 penetrating through the entire thickness of the multilayer printed wiring board 53 in order to connect the internal-layer wiring trace 13 with the external layer wiring trace 14, as shown in FIG. 17. The via-plugs 52 penetrate through the entire thickness of the multilayer printed wiring board 53, and should have a sufficiently large diameter as compared to the third via-plugs 47, wherein the inner diameter L7 of the via-plugs 52 is generally 0.2 to 0.3 mm with a land diameter L8 thereof being 0.6 to 0.7 mm. Such a structure cannot realize a high density multilayer printed wiring board 53.

In the structure of the present embodiment, the internal-layer wiring traces 13 are formed on the inner surface of the second insulating layer 12 thereby allowing formation of the small-diameter third via-plugs 47 that connect together the internal-layer wiring traces 13 and external layer wiring traces 14, in addition to the first via-plugs 16 which are formed after the formation of the recessed-holes 17 for the stacked body 22. The recessed-holes 17 and the third via-plugs can be formed using a common drill.

As described heretofore, in one embodiment of the present invention, the first via-plug is formed on the inner wall of a first through-hole penetrating through the first insulating layer and connects together the internal-layer wiring traces with each other. The second via-plug formed inside the first via-plug and isolated therefrom by insulating resin connects together the external-layer wiring traces. This structure reduces the occupied area of the via-plugs whereby a higher wiring density can be achieved.

In addition, by using a configuration wherein the first and second via-plugs configure a signal wiring layer and a ground wiring layer, the characteristic impedance of the wiring layer can be matched to that of the other wiring traces, enabling a reflection noise to be reduced. In an alternative, by using a configuration wherein these two via-plugs configure a power source wiring layer and a ground wiring layer, the loop impedance in the multilayer printed wiring board can be reduced.

While the invention has been particularly shown and described with reference to exemplary embodiment and modifications thereof, the invention is not limited to these embodiment and modifications. It will be understood by those of ordinary skill in the art that various changes in form and details may be made therein without departing from the spirit and scope of the present invention as defined in the claims.

What is claimed is:

1. A method for manufacturing a multilayer printed wiring board, comprising:
forming a stacked body that includes a first insulating layer, a second insulating layer disposed on a surface of the first insulating layer, and an internal-layer wiring trace formed between the first insulating layer and the second insulating layer;
forming a first through-hole that penetrates through the stacked body;
forming a first conductive layer at least on the inner wall of the first through-hole to form a hollow cylindrical conductive plug therein;
forming a recessed-hole penetrating through the second insulating layer, the recessed-hole having a diameter larger than a diameter of the first through-hole and coaxial therewith;
embedding a resin layer inside the hollow cylindrical conductive plug and within the recessed-hole to form an insulating plug penetrating through the stacked body;
forming a second through-hole within the insulating plug penetrating therethrough; and
forming a second conductive layer within the second through-hole to form a conductive plug penetrating the stacked body.

2. The method for manufacturing a multilayer printed wiring board according to claim 1, wherein the stacked body forming includes forming an external-layer wiring trace layer on an exposed surface of the second insulating layer, forming a via-hole that penetrates through the second insulating layer, and forming a via-plug on an inner wall of the via-hole to connect together the internal-layer wiring trace and the external-layer wiring trace.

3. The method for manufacturing a multilayer printed wiring board according to claim 1, wherein the insulating plug is made of thermosetting resin.

4. The method for manufacturing a multilayer printed wiring board according to claim 1, wherein one of the first conductive layer and second conductive layer is formed by a plating technique.

5. A multilayer printed wiring board comprising:
a stacked body including a first insulating layer, a pair of second insulating layers sandwiching therebetween the first insulating layer, a pair of internal-layer wiring traces each formed between the first insulating layer and one of the second insulating layers, and a pair of external-layer wiring traces each formed on an exposed surface of a corresponding one of the second insulating layers, the first insulating layer including therein a first through-hole, the first and second insulating layers including therein a second through-hole coaxial with the first through-hole and isolated therefrom by an insulating plug disposed therebetween;
a first via-plug formed on the inner wall of the first through-hole to connect together the internal-layer wiring traces with each other;
a second via-plug formed on the inner wall of the second through-hole to connect together the external layer wiring traces with each other.

6. The multilayer printed wiring board according to claim 5, further comprising: a third via-plug formed in a via-hole that penetrates through the second insulating layer to connect together the external-layer wiring trace and internal-layer wiring trace.

7. The multilayer printed wiring board according to claim 5, wherein the insulating plug is made of thermosetting resin.

8. The multilayer printed wiring board according to claim 5, wherein one of the first and second via-plugs is configured by a plating layer.

9. The multilayer printed wiring board according to claim 5, wherein the second via-plug is of a hollow cylindrical shape.
